(19) United States
(12) Patent Application Publication
(10) Pub. No.: US 2026/0351528 A1
(43) Pub. Date: Nov. 5, 2026

(54) PLASMA PROCESSING APPARATUS

(71) Applicant: Tokyo Electron Limited, Tokyo (JP)

(72) Inventor: Yuki KUMAGAI, Miyagi (JP)

(21) Appl. No.: 19/704,945

(22) Filed: Jun. 11, 2026

Related U.S. Application Data
(63) Continuation of application No. PCT/JP2024/042075, filed on Nov. 28, 2024.

(30) Foreign Application Priority Data
Dec. 12, 2023 (JP) 2023-209077

(51) Int. Cl. H01J 37/32

(52) U.S. Cl. CPC H01J 37/32642; H01J 2237/1502

(57) ABSTRACT

A plasma processing apparatus includes: a substrate support configured to support a substrate to be processed; an inner ring supported by the substrate support; and an outer ring partially disposed outward of the inner ring, wherein a substrate support surface of the substrate support is higher than an upper surface of the inner ring, an inner peripheral surface of the outer ring is located outward of a position corresponding to an outermost periphery of the substrate, and an outer peripheral surface of the inner ring and the inner peripheral surface of the outer ring form a labyrinth-shaped space therebetween.

### CROSS-REFERENCE TO RELATED APPLICATIONS

This application is a continuation of International Application No. PCT/JP2024/042075, filed on Nov. 28, 2024 and designating the U.S., which claims priority to Japanese Patent Application No. 2023-209077, filed on Dec. 12, 2023. The contents of these applications are incorporated herein by reference in their entirety.

### TECHNICAL FIELD

The present disclosure relates to a plasma processing apparatus.

### BACKGROUND ART

For example, Japanese Laid-open Patent Publication No. 2018-160666 discloses a substrate processing apparatus including an inner focus ring disposed near a substrate placed on a stage in a processing chamber, and a middle focus ring disposed outward of the inner focus ring and movable up and down by a moving mechanism.

### SUMMARY

According to one aspect of the present disclosure, a plasma processing apparatus includes: a substrate support configured to support a substrate to be processed; an inner ring supported by the substrate support; and an outer ring partially disposed outward of the inner ring, wherein a substrate support surface of the substrate support is higher than an upper surface of the inner ring, an inner peripheral surface of the outer ring is located outward of a position corresponding to an outermost periphery of the substrate, and an outer peripheral surface of the inner ring and the inner peripheral surface of the outer ring form a labyrinth-shaped space therebetween.

### BRIEF DESCRIPTION OF THE DRAWINGS

FIG. 1 is a diagram illustrating a configuration of a plasma processing system including a plasma processing apparatus according to an embodiment;

FIG. 2 is a diagram illustrating an edge ring of a plasma processing apparatus according to a first embodiment;

FIG. 3 is a diagram illustrating an edge ring of a plasma processing apparatus according to a second embodiment;

FIG. 4 is a diagram illustrating an edge ring of a plasma processing apparatus according to a third embodiment;

FIG. 5 is a diagram illustrating an edge ring of a plasma processing apparatus according to a fourth embodiment;

FIG. 6 is a diagram illustrating a plasma processing apparatus according to a fifth embodiment; and

FIG. 7 is a diagram illustrating a plasma processing apparatus according to a sixth embodiment.

### DETAILED DESCRIPTION

Hereinafter, embodiments of the present disclosure will be described with reference to the drawings. In the present specification and the drawings, the same components are denoted by the same reference numerals, and redundant descriptions thereof will be omitted. In order to facilitate understanding, the components in the drawings may not be to scale. In directions such as parallel, perpendicular, orthogonal, horizontal, vertical, up-down, and left-right, deviation is allowed to the extent that the effects of the embodiments are not impaired. The shape of a corner is not limited to a right angle, and may be rounded. The terms “parallel”, “perpendicular”, “orthogonal”, “horizontal”, and “vertical” may include “substantially parallel”, “substantially perpendicular”, “substantially orthogonal”, “substantially horizontal”, and “substantially vertical”, respectively.

### Plasma Processing System

An example configuration of a plasma processing system will be described below.

The plasma processing system includes a capacitively coupled plasma processing apparatus 1 and a controller 2. The capacitively coupled plasma processing apparatus 1 includes a plasma processing chamber 10, a gas supply 20, a power source 30, and an exhaust system 40. Further, the plasma processing apparatus 1 includes a substrate support 11 and a gas introduction section. The gas introduction section is configured to introduce at least one processing gas into the plasma processing chamber 10. The gas introduction section includes a showerhead 13. The substrate support 11 is disposed inside the plasma processing chamber 10. The showerhead 13 is disposed above the substrate support 11. In one embodiment, the showerhead 13 constitutes at least a part of a ceiling of the plasma processing chamber 10. The plasma processing chamber 10 has a plasma processing space 10s defined by the showerhead 13, a side wall 10a of the plasma processing chamber 10, and the substrate support 11. The plasma processing chamber 10 includes at least one gas supply port for supplying at least one processing gas into the plasma processing space 10s, and at least one gas exhaust port for exhausting gas from the plasma processing space. The side wall 10a is grounded. The showerhead 13 and the substrate support 11 are electrically insulated from a housing of the plasma processing chamber 10.

The substrate support 11 supports each of a substrate (wafer) W, an inner ring 113, and an outer ring 114. The substrate support 11 includes a main body 120 and a peripheral part 130. The main body 120 has a center region (substrate support surface) 120S for supporting the substrate W. The main body 120 supports the substrate W and the inner ring 113. Further, the peripheral part 130 has an annular region (ring support surface) 130S for supporting the outer ring 114. The peripheral part 130 supports the outer ring 114. The peripheral part 130 is provided outward of the main body 120 so as to be movable in an up-down direction relative to the main body 120. The annular region 130S of the peripheral part 130 surrounds the center region 120S of the main body 120 in a plan view. The substrate W is disposed in the center region 120S of the main body 120, and the outer ring 114 is disposed in the annular region 130S of the peripheral part 130 so as to surround the substrate W in the center region 120S of the main body 120. In one embodiment, the main body 120 includes a base and an electrostatic chuck. The base includes a conductive member. The conductive member of the base functions as a lower electrode. The electrostatic chuck is disposed on the base. The upper surface of the electrostatic chuck has the substrate support surface 120S. The inner ring 113 and the outer ring 114 are, for example, an edge ring. Further, although not illustrated, the substrate support 11 may include a temperature control module configured to control at least one of the electrostatic chuck, the inner ring 113, the outer ring 114, or the substrate to a target temperature. The temperature control module may include a heater, a heat transfer medium, or a flow path, or a combination thereof. A heat transfer fluid, such as brine or gas, flows through the flow path. Further, the substrate support 11 may include a heat transfer gas supply configured to supply a heat transfer gas between the back surface of the substrate W and the substrate support surface 120S.

The showerhead 13 is configured to introduce at least one processing gas from the gas supply 20 into the plasma processing space 10s. The showerhead 13 includes at least one gas supply port 13a, at least one gas diffusion chamber 13b, and multiple gas introduction ports 13c. The processing gas supplied to the gas supply port 13a passes through the gas diffusion chamber 13b and is introduced into the plasma processing space 10s through the gas introduction ports 13c. Further, the showerhead 13 includes a conductive member. The conductive member of the showerhead 13 functions as an upper electrode. The gas introduction section may include, in addition to the showerhead 13, one or more side gas injectors (SGIs) attached to one or more openings formed in the side wall 10a.

The gas supply 20 may include at least one gas source 21 and at least one flow rate controller 22. In one embodiment, the gas supply 20 is configured to supply at least one processing gas from a corresponding gas source 21 to the showerhead 13 via a corresponding flow rate controller 22. Each flow rate controller 22 may include, for example, a mass flow controller or a pressure control type flow rate controller. Further, the gas supply 20 may include one or more flow modulation devices configured to modulate or pulse the flow rate of the at least one processing gas.

The power source 30 includes an RF power source 31 coupled to the plasma processing chamber 10 through at least one impedance matching circuit. The RF power source 31 is configured to supply at least one RF signal (RF power), such as a source RF signal or a bias RF signal, to the conductive member of the substrate support 11 and/or the conductive member of the showerhead 13. As a result, plasma is formed from at least one processing gas supplied into the plasma processing space 10s. Thus, the RF power source 31 can function as at least a part of a plasma generator configured to form plasma from one or more processing gases in the plasma processing chamber 10. Further, by supplying a bias RF signal to the conductive member of the substrate support 11, a bias potential is generated in the substrate W, and ionic components in the formed plasma can be drawn to the substrate W.

In one embodiment, the RF power source 31 includes a first RF generator 31a and a second RF generator 31b. The first RF generator 31a is coupled to the conductive member of the substrate support 11 and/or the conductive member of the showerhead 13 via at least one impedance matching circuit, and is configured to generate a source RF signal (source RF power) for plasma generation. In one embodiment, the source RF signal has a frequency in a range of 13 MHz to 150 MHz. In one embodiment, the first RF generator 31a may be configured to generate a plurality of source RF signals having different frequencies. The generated one or plurality of source RF signals are supplied to the conductive member of the substrate support 11 and/or the conductive member of the showerhead 13. The second RF generator 31b is coupled to the conductive member of the substrate support 11 via at least one impedance matching circuit, and is configured to generate a bias RF signal (bias RF power). In one embodiment, the bias RF signal has a lower frequency than the source RF signal. In one embodiment, the bias RF signal has a frequency in a range of 400 kHz to 13.56 MHz. In one embodiment, the second RF generator 31b may be configured to generate a plurality of bias RF signals having different frequencies. The generated one or plurality of bias RF signals are supplied to the conductive member of the substrate support 11. Further, in various embodiments, at least one of the source RF signal or the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is connected to the conductive member of the substrate support 11, and is configured to generate a first DC signal. The generated first DC signal is applied to the conductive member of the substrate support 11. In one embodiment, the first DC signal may be applied to another electrode, such as an electrode in the electrostatic chuck. In one embodiment, the second DC generator 32b is connected to the conductive member of the showerhead 13, and is configured to generate a second DC signal. The generated second DC signal is applied to the conductive member of the showerhead 13. In various embodiments, at least one of the first DC signal or the second DC signal may be pulsed. The first and second DC generators 32a and 32b may be provided in addition to the RF power source 31, and the first DC generator 32a may be provided in place of the second RF generator 31b.

The exhaust system 40 can be connected to a gas exhaust port 10e provided at the bottom of the plasma processing chamber 10, for example. The exhaust system 40 may include a pressure regulating valve and a vacuum pump. The pressure in the plasma processing space 10s is regulated by the pressure regulating valve. The vacuum pump may include a turbomolecular pump, a dry pump, or a combination thereof.

The controller 2 processes computer-executable instructions that cause the plasma processing apparatus 1 to perform various processes described in the present disclosure. The controller 2 can be configured to control each component of the plasma processing apparatus 1 to perform various processes described herein. In one embodiment, a part or the entirety of the controller 2 may be included in the plasma processing apparatus 1. The controller 2 may include, for example, a computer 2a. The computer 2a may include, for example, a processor (central processing unit (CPU)) 2a1, a storage 2a2, and a communication interface 2a3. The processor 2a1 can be configured to execute various control operations based on a program stored in the storage 2a2. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### First Embodiment

A plasma processing apparatus according to a first embodiment will be described. The plasma processing apparatus according to the first embodiment includes a substrate support configured to support a substrate to be processed, an inner ring supported by the substrate support and disposed under the substrate, and an outer ring disposed outward of the substrate and the inner ring. Further, in the plasma processing apparatus according to the first embodiment, a substrate support surface of the substrate support is higher than an upper surface of the inner ring. The substrate support surface supports the substrate. Further, in the plasma processing apparatus according to the first embodiment, an inner peripheral surface of the outer ring is located outward of an outermost periphery of the substrate. The plasma processing apparatus according to the first embodiment has a labyrinth structure between an outer peripheral surface of the inner ring and the inner peripheral surface of the outer ring.

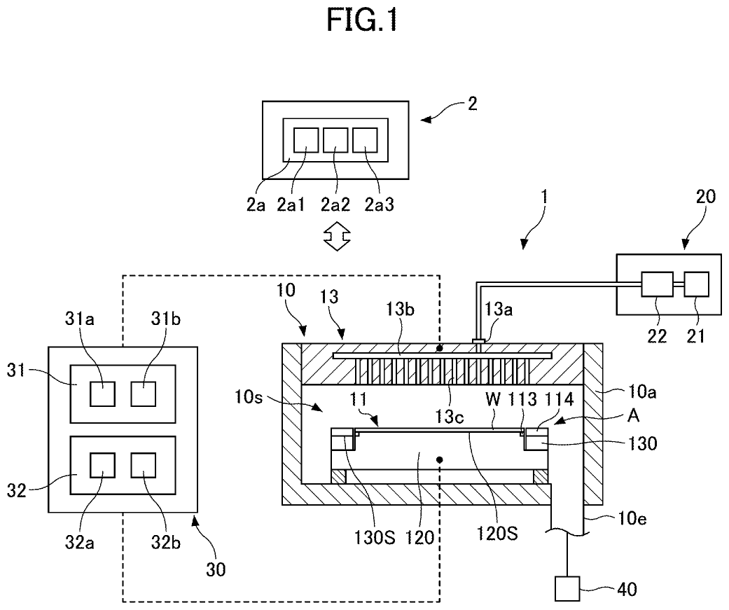

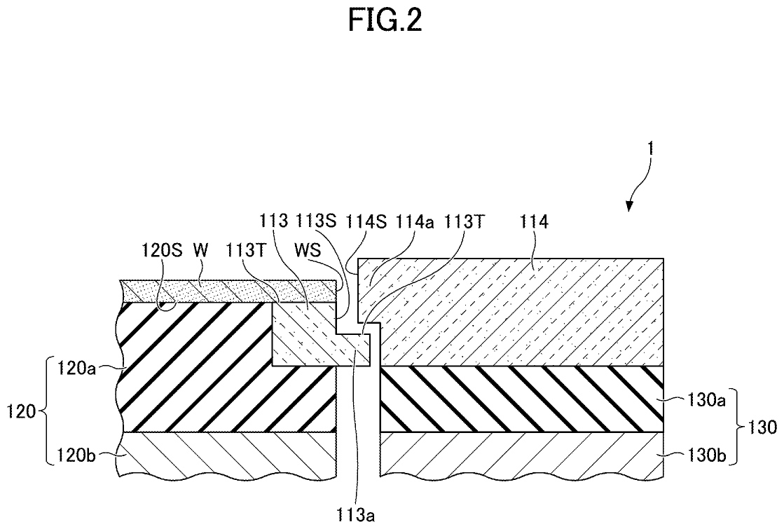

The inner ring and the outer ring of the plasma processing apparatus according to the first embodiment will be described in detail with reference to FIG. 2. FIG. 2 is a diagram illustrating the inner ring 113 and the outer ring 114 of the plasma processing apparatus 1, which is an example of the plasma processing apparatus according to the first embodiment. FIG. 2 is a cross-sectional view illustrating an outline of a portion indicated by an arrow A of FIG. 1.

The plasma processing apparatus 1 includes the inner ring 113 disposed under the substrate W to be subjected to plasma processing. The substrate support surface 120S of the main body 120 for supporting the substrate W is higher than an upper surface 113T of the inner ring 113. Further, the plasma processing apparatus 1 includes the outer ring 114 disposed outward of the substrate W and the inner ring 113. An inner peripheral surface 114S of the outer ring 114 is located outward of an outermost periphery WS of the substrate W.

The main body 120 of the plasma processing apparatus 1 includes a dielectric layer 120a and a conductive layer 120b.

The dielectric layer 120a is, for example, a ceramic layer composed of a ceramic. The dielectric layer 120a forms, for example, an electrostatic chuck configured to attract the substrate W. The dielectric layer 120a includes an electrode for the electrostatic chuck. The electrostatic chuck formed by the dielectric layer 120a may be configured to attract the inner ring 113.

The conductive layer 120b is composed of, for example, a metal such as aluminum. The conductive layer 120b functions as a lower electrode. The conductive layer 120b supports the dielectric layer 120a.

The peripheral part 130 of the plasma processing apparatus 1 includes a dielectric layer 130a and a conductive layer 130b.

The dielectric layer 130a is, for example, a ceramic layer composed of a ceramic. The dielectric layer 130a forms, for example, an electrostatic chuck. The dielectric layer 130a includes an electrode for the electrostatic chuck.

The conductive layer 130b is composed of, for example, a metal such as aluminum. The conductive layer 130b supports the dielectric layer 130a.

The peripheral part 130 is movable up and down relative to the main body 120. Because the peripheral part 130 is movable up and down relative to the main body 120, for example, even if the thickness of the outer ring 114 supported by the peripheral part 130 is reduced by plasma, the outer ring 114 can be moved up by an amount corresponding to the reduced thickness. By moving the outer ring 114 up, the influence of a change in plasma caused by a change in a dimension of the outer ring 114 can be suppressed. By suppressing the influence of the change in plasma caused by the change in the dimension of the outer ring 114, for example, variations in plasma processing in the plasma processing apparatus 1 can be suppressed.

In a case where what is known as an edge ring is moved up and down, if a gap is provided between a main body and the edge ring in order to move the edge ring, there would be a possibility that particles enter through the gap and damage a substrate and the lower side of the edge ring.

In view of the above, the inventor has found that intrusion of particles can be suppressed by dividing an edge ring into an inner ring and an outer ring and providing a labyrinth structure between the outer peripheral surface of the inner ring and the inner peripheral surface of the outer ring.

The inner ring 113 includes, at an outer peripheral edge portion, a projection 113a protruding outward. The outer ring 114 includes, at an inner peripheral edge portion, a projection 114a protruding inward. The projection 113a and the projection 114a together enable the plasma processing apparatus 1 to have a labyrinth structure between an outer peripheral surface 113S of the inner ring 113 and the inner peripheral surface 114S of the outer ring 114. Further, the projection 113a and the projection 114a prevent the dielectric layer 120a, the conductive layer 120b, the dielectric layer 130a, and the conductive layer 130b from being exposed to the plasma processing space, as viewed from the plasma processing space.

The plasma processing apparatus according to the first embodiment has the labyrinth structure between the outer peripheral surface of the inner ring and the inner peripheral surface of the outer ring. Thus, intrusion of particles from between the inner ring and the outer ring can be suppressed.

### Second Embodiment

A plasma processing apparatus according to a second embodiment will be described. In addition to the configuration of the plasma processing apparatus according to the first embodiment, in the plasma processing apparatus according to the second embodiment, the outer ring includes a lower projection extending downward from the inner peripheral side and configured to protect a ceramic layer of a ring support supporting the outer ring.

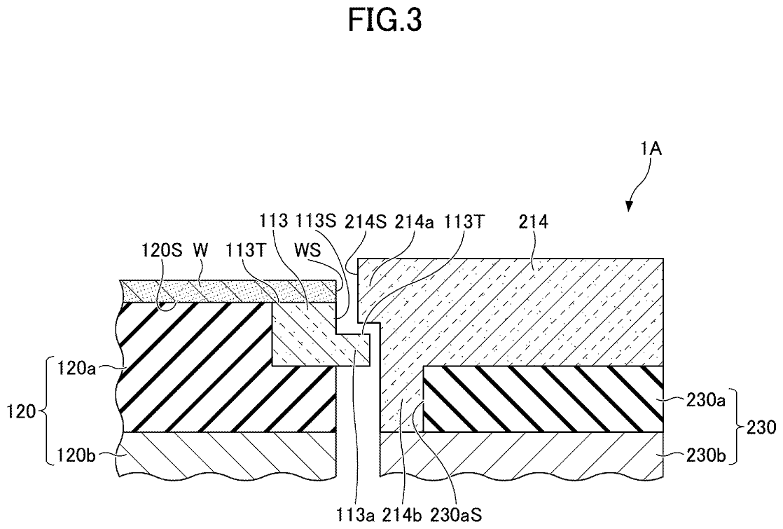

The inner ring and the outer ring of the plasma processing apparatus according to the second embodiment will be described in detail with reference to FIG. 3. FIG. 3 is a diagram illustrating the inner ring 113 and an outer ring 214 of a plasma processing apparatus 1A, which is an example of the plasma processing apparatus according to the second embodiment. For the inner ring 113, the dielectric layer 120a, and the conductive layer 120b, reference is made to the description of the plasma processing apparatus 1, and a description thereof will be omitted here.

The plasma processing apparatus 1A includes a peripheral part 230 instead of the peripheral part 130 of the plasma processing apparatus 1. The peripheral part 230 of the plasma processing apparatus 1A includes a dielectric layer 230a and a conductive layer 230b.

The dielectric layer 230a is a ceramic layer composed of, for example, a ceramic. The dielectric layer 230a forms, for example, an electrostatic chuck. The dielectric layer 230a includes an electrode for the electrostatic chuck.

The conductive layer 230b is composed of, for example, a metal such as aluminum. The conductive layer 230b supports the dielectric layer 230a.

The inner ring 113 includes, at the outer peripheral edge portion, the projection 113a protruding outward. An inner peripheral surface 214S of the outer ring 214 is located outward of the outermost periphery WS of the substrate W. The outer ring 214 includes, at an inner peripheral edge portion, a projection 214a protruding inward. The projection 113a and the projection 214a allows the plasma processing apparatus 1A to have a labyrinth structure between the outer peripheral surface 113S of the inner ring 113 and the inner peripheral surface 214S of the outer ring 214. Further, the projection 113a and the projection 214a prevent the dielectric layer 120a, the conductive layer 120b, the dielectric layer 230a, and the conductive layer 230b from being exposed to the plasma processing space, as viewed from the plasma processing space.

The outer ring 214 further includes a lower projection 214b protruding downward and configured to protect the dielectric layer 230a of the peripheral part 230 on which the outer ring 214 is placed. The lower projection 214b is provided so as to cover an inner surface 230aS of the dielectric layer 230a.

The plasma processing apparatus according to the second embodiment has the labyrinth structure between the outer peripheral surface of the inner ring and the inner peripheral surface of the outer ring. Thus, intrusion of particles from between the inner ring and the outer ring can be suppressed. In addition, the plasma processing apparatus according to the second embodiment includes the lower projection protruding downward, and thus, the ceramic layer of the peripheral part on which the outer ring is placed can be protected.

The peripheral part 230 is an example of the ring support and the dielectric layer 230a is an example of the ceramic layer.

### Third Embodiment

A plasma processing apparatus according to a third embodiment will be described. Similar to the plasma processing apparatus according to the first embodiment, in the plasma processing apparatus according to the third embodiment, the inner ring includes, on the outer peripheral surface, the projection extending outward. Further, in the plasma processing apparatus according to the third embodiment, the outer ring includes, in the inner peripheral surface, a groove into which the projection is inserted.

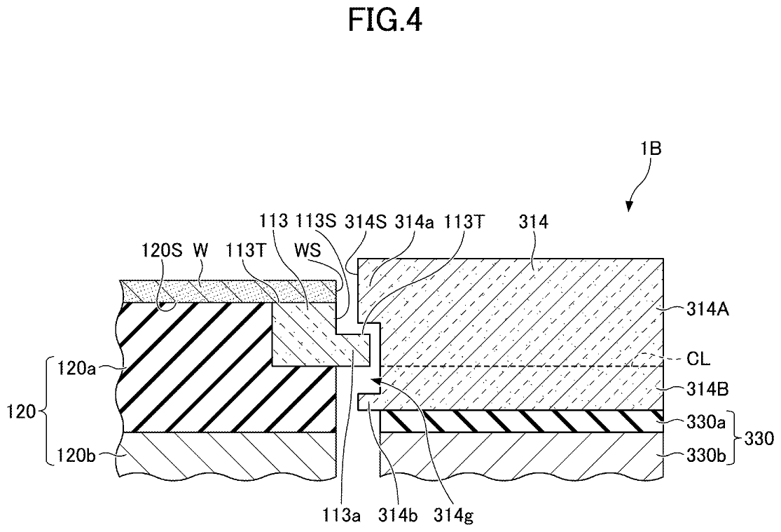

The inner ring and the outer ring of the plasma processing apparatus according to the third embodiment will be described with reference to FIG. 4. FIG. 4 is a diagram illustrating the inner ring 113 and an outer ring 314 of a plasma processing apparatus 1B, which is an example of the plasma processing apparatus according to the third embodiment. For the inner ring 113, the dielectric layer 120a, and the conductive layer 120b, reference is made to the description of the plasma processing apparatus 1, and a description thereof will be omitted here.

The plasma processing apparatus 1B includes a peripheral part 330 instead of the peripheral part 130 of the plasma processing apparatus 1. The peripheral part 330 of the plasma processing apparatus 1B includes a dielectric layer 330a and a conductive layer 330b.

The dielectric layer 330a is, for example, a ceramic layer composed of a ceramic. The dielectric layer 330a forms, for example, an electrostatic chuck. The dielectric layer 330a includes an electrode for the electrostatic chuck.

The conductive layer 330b is composed of, for example, a metal such as aluminum. The conductive layer 330b supports the dielectric layer 330a.

The inner ring 113 includes, at the outer peripheral edge portion, the projection 113a protruding outward. The outer ring 314 includes, at an inner peripheral edge portion, a projection 314a protruding inward. An inner peripheral surface 314S of the outer ring 314 is provided outward of the outermost periphery WS of the substrate W. In addition, the outer ring 314 includes, at an inner peripheral edge portion, a projection 314b protruding inward. A groove 314g into which the projection 113a is inserted is defined by the projection 314a and the projection 314b. The projection 113a, the projection 314a, and the projection 314b (and the groove 314g) together enable the plasma processing apparatus 1B to have a labyrinth structure between the outer peripheral surface 113S of the inner ring 113 and the inner peripheral surface 314S of the outer ring 314. Further, the projection 113a, the projection 314a, and the projection 314b prevent the dielectric layer 120a, the conductive layer 120b, the dielectric layer 330a, and the conductive layer 330b from being exposed to the plasma processing space, as viewed from the plasma processing space.

The outer ring 314 is formed by coupling together an upper member 314A and a lower member 314B, which are formed by being divided in the up-down direction as indicated by a line CL of FIG. 4. For example, before the upper member 314A and the lower member 314B of the outer ring 314 are coupled together, the projection 113a of the inner ring 113 is inserted into a portion that is to become the groove 314g. Then, by coupling together the upper member 314A and the lower member 314B, the projection 113a is brought into a state of being inserted into the groove 314g.

The plasma processing apparatus according to the third embodiment has the labyrinth structure between the outer peripheral surface of the inner ring and the inner peripheral surface of the outer ring. Thus, intrusion of particles from between the inner ring and the outer ring can be suppressed. In addition, in the plasma processing apparatus according to the third embodiment, the projection extending outward from the outer peripheral surface of the inner ring is inserted into the groove formed in the inner peripheral surface of the outer ring. Thus, intrusion of particles can be suppressed even when the outer ring moves up and down.

### Fourth Embodiment

A plasma processing apparatus according to a fourth embodiment will be described. The plasma processing apparatus according to the fourth embodiment differs from the plasma processing apparatus according to the first embodiment in that, the inner ring includes a first flat plate portion extending outward and a first protruding portion extending upward, and the outer ring includes a second flat plate portion extending inward and a second protruding portion extending downward. Further the outer ring includes a lower projection.

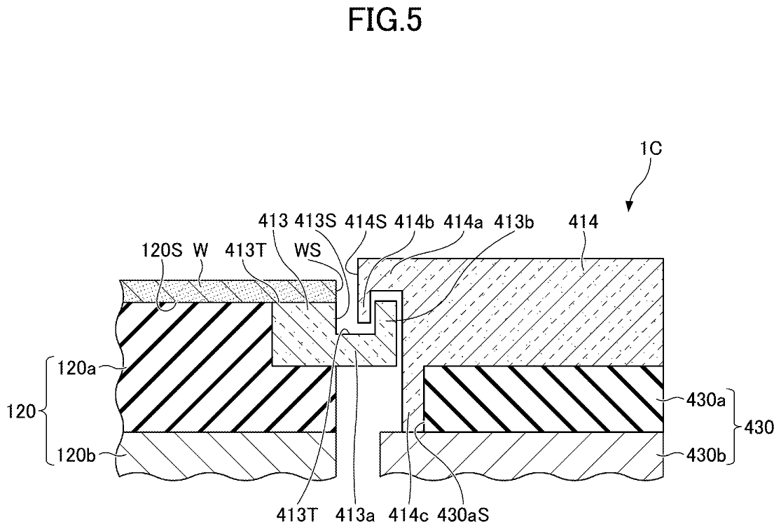

The inner ring and the outer ring of the plasma processing apparatus according to the fourth embodiment will be described in detail with reference to FIG. 5. FIG. 5 is a diagram illustrating an inner ring 413 and an outer ring 414 of a plasma processing apparatus 1C, which is an example of the plasma processing apparatus according to the fourth embodiment. For the dielectric layer 120a and the conductive layer 120b, reference is made to the description of the plasma processing apparatus 1, and a description thereof will be omitted here.

The plasma processing apparatus 1C includes a peripheral part 430 instead of the peripheral part 130 of the plasma processing apparatus 1. The peripheral part 430 of the plasma processing apparatus 1C includes a dielectric layer 430a and a conductive layer 430b.

The dielectric layer 430a is a ceramic layer composed of, for example, a ceramic. The dielectric layer 430a forms, for example, an electrostatic chuck. The dielectric layer 430a includes an electrode for the electrostatic chuck.

The conductive layer 430b is composed of, for example, a metal such as aluminum. The conductive layer 430b supports the dielectric layer 430a.

The inner ring 413 includes, at an outer peripheral edge portion, a flat plate portion 413a extending outward, and a protruding portion 413b extending upward from an outer end portion of the flat plate portion 413a. The substrate support surface 120S of the main body 120 for supporting the substrate W is higher than an upper surface 413T of the inner ring 413. The outer ring 414 includes, at an inner peripheral edge portion, a flat plate portion 414a extending inward, and a protruding portion 414b extending downward from an inner end portion of the flat plate portion 414a. The outer ring 414 further includes a lower projection 414c protruding downward and configured to protect the dielectric layer 430a of the peripheral part 430 on which the outer ring 414 is placed. The lower projection 414c is provided so as to cover an inner surface 430aS of the dielectric layer 430a. An inner peripheral surface 414S of the outer ring 414 is located outward of the outermost periphery WS of the substrate W.

The flat plate portion 413a, the protruding portion 413b, the flat plate portion 414a, and the protruding portion 414b together enable the plasma processing apparatus 1C to have a labyrinth structure between an outer peripheral surface 413S of the inner ring 413 and the inner peripheral surface 414S of the outer ring 414. Further, the flat plate portion 413a and the flat plate portion 414a prevent the dielectric layer 120a, the conductive layer 120b, the dielectric layer 430a, and the conductive layer 430b from being exposed to the plasma processing space, as viewed from the plasma processing space.

The plasma processing apparatus according to the fourth embodiment has the labyrinth structure between the outer peripheral surface of the inner ring and the inner peripheral surface of the outer ring. Thus, intrusion of particles from between the inner ring and the outer ring can be suppressed. In addition, the plasma processing apparatus according to the fourth embodiment includes the first protruding portion and the second protruding portion, and thus intrusion of particles can be further suppressed.

The flat plate portion 413a is an example of the first flat plate portion, the protruding portion 413b is an example of the first protruding portion, the flat plate portion 414a is an example of the second flat plate portion, and the protruding portion 414b is an example of the second protruding portion.

### Fifth Embodiment

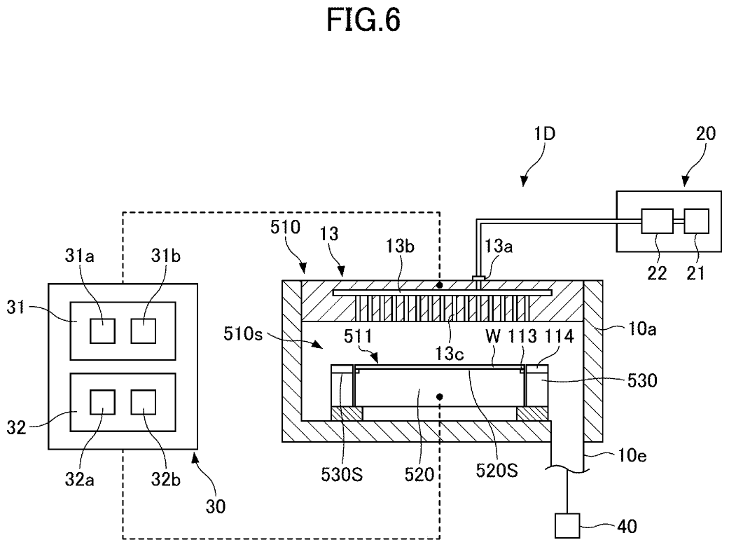

A plasma processing apparatus according to a fifth embodiment will be described. The plasma processing apparatus according to the fifth embodiment includes a ring support configured to support an outer ring, in addition to a substrate support configured to support a substrate to be processed. FIG. 6 is a diagram illustrating a plasma processing apparatus 1D, which is an example of the plasma processing apparatus according to the fifth embodiment. The plasma processing apparatus 1D includes a plasma processing chamber 510, a gas supply 20, a power source 30, and an exhaust system 40. For configurations of the plasma processing apparatus 1D common to those of the plasma processing apparatus 1, reference is made to the description of the plasma processing apparatus 1, and a detailed description thereof will be omitted.

The plasma processing apparatus 1D includes, instead of the substrate support 11 of the plasma processing apparatus 1, a substrate support 511 configured to support each of a substrate W and an inner ring 113, and includes a ring support 530 disposed separately from the substrate support 511 and configured to support an outer ring 114.

The substrate support 511 includes a main body 520. The main body 520 has a center region (substrate support surface) 520S for supporting the substrate W. The main body 520 supports the substrate W and the inner ring 113.

The ring support 530 has an annular region (ring support surface) 530 S for supporting the outer ring 114. The ring support 530 supports the outer ring 114. The ring support 530 is provided outward of the main body 520 of the substrate support 511. The ring support 530 supports the outer ring 114 so as to be movable in the up-down direction. The annular region 530S of the ring support 530 surrounds the center region 520S of the main body 520 in a plan view. The substrate W is disposed in the center region 520S of the main body 520, and the outer ring 114 is disposed in the annular region 530S of the ring support 530 so as to surround the substrate W in the center region 520S of the main body 520.

The main body 520 has a configuration similar to that of the main body 120. The ring support 530 has a configuration similar to that of the peripheral part 130 of the substrate support 11. Further, each of the plasma processing apparatuses according to the second embodiment to the fourth embodiment may include a ring support configured to support an outer ring, in addition to a substrate support configured to support a substrate to be processed.

Similar to the plasma processing apparatuses according to the first embodiment to the fourth embodiment, the plasma processing apparatus according to the fifth embodiment can suppress intrusion of particles from between the inner ring and the outer ring. Further, according to the plasma processing apparatus of the fifth embodiment, providing the ring support allows for independent handling from the substrate support.

### Sixth Embodiment

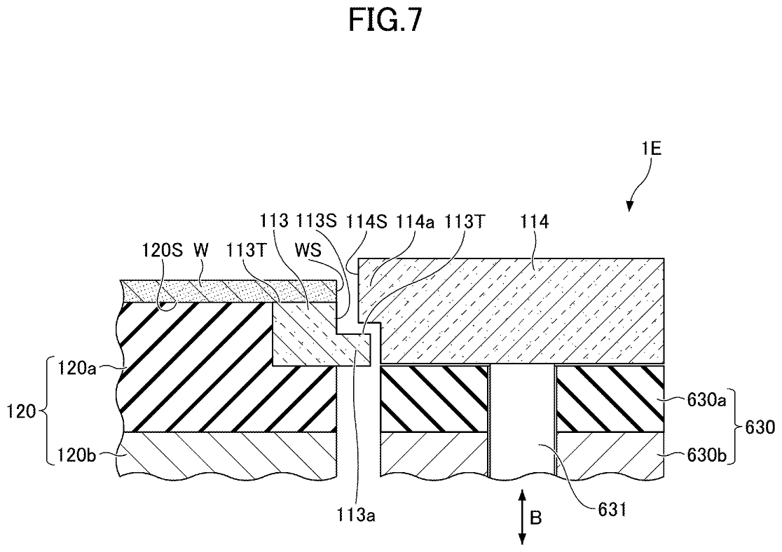

A plasma processing apparatus according to a sixth embodiment will be described. The plasma processing apparatus according to the sixth embodiment includes a pin configured to move the outer ring in the up-down direction. FIG. 7 is a diagram illustrating a plasma processing apparatus 1E, which is an example of the plasma processing apparatus according to the sixth embodiment. The plasma processing apparatus 1E includes a peripheral part 630, instead of the peripheral part 130 of the plasma processing apparatus 1. Further, the plasma processing apparatus 1E includes a pin 631 configured to move the outer ring 114 in the up-down direction. A plurality of pins 631 may be provided so as to stably move the outer ring 114 in the up-down direction.

Similar to the peripheral part 130, the peripheral part 630 includes a dielectric layer 630a and a conductive layer 630b. The peripheral part 630 is fixed to the main body 120. Conversely, the pin 631 is movable in the up-down direction as indicated by an arrow B. In response to the pin 631 being moved in the up-down direction, the outer ring 114 is moved in the up-down direction.

As in the plasma processing apparatus according to the sixth embodiment, each of the plasma processing apparatuses according to the second embodiment to the fifth embodiment may include a pin configured to move an outer ring in the up-down direction, and the outer ring may be moved in the up-down direction by the pin.

Similar to the plasma processing apparatuses according to the first embodiment to the fifth embodiment, the plasma processing apparatus according to the sixth embodiment can suppress intrusion of particles from between the inner ring and the outer ring. Further, in the plasma processing apparatus according to the sixth embodiment, the outer ring can be moved in the up-down direction by the pin.

The plasma processing apparatuses according to the embodiments disclosed herein should be considered exemplary and non-restrictive in all respects. The above embodiments can be modified and improved in various forms without departing from the scope and the spirit of the appended claims. The matters described in the above embodiments can be employed in other configurations as long as no contradiction occurs, and can be combined as long as no contradiction occurs.

The present disclosure provides a technique for suppressing intrusion of particles from between an inner ring and an outer ring.

What is claimed is:

1. A plasma processing apparatus comprising:
a substrate support configured to support a substrate to be processed;
an inner ring supported by the substrate support; and
an outer ring partially disposed outward of the inner ring, wherein
a substrate support surface of the substrate support is higher than an upper surface of the inner ring,
an inner peripheral surface of the outer ring is located outward of a position corresponding to an outermost periphery of the substrate, and
an outer peripheral surface of the inner ring and the inner peripheral surface of the outer ring form a labyrinth-shaped space therebetween.

2. The plasma processing apparatus according to claim 1, wherein
the outer ring includes a lower projection extending downward from an inner peripheral side thereof and configured to protect a ceramic layer of a ring support supporting the outer ring.

3. The plasma processing apparatus according to claim 1, wherein
the inner ring includes, on the outer peripheral surface, a projection extending outward,
the outer ring includes, in the inner peripheral surface, a groove into which the projection is inserted, and
the upper surface of the inner ring is an upper surface of the projection.

4. The plasma processing apparatus according to claim 1, wherein
the inner ring includes a first flat plate portion extending outward and a first protruding portion extending upward,
the outer ring includes a second flat plate portion extending inward and a second protruding portion extending downward, and
the upper surface of the inner ring is an upper surface of the first flat plate portion.

5. The plasma processing apparatus according to claim 1, wherein the substrate support is configured to support the outer ring.

6. The plasma processing apparatus according to claim 1, further comprising:
a ring support disposed separately from the substrate support and configured to support the outer ring.

7. The plasma processing apparatus according to claim 1, wherein the substrate support includes a pin configured to move the outer ring in an up-down direction.

8. A plasma processing apparatus comprising:
a chamber;
a substrate support disposed inside the chamber, and including an electrically-conductive base and an electrostatic chuck disposed on the base;
a peripheral part surrounding the substrate support;
an inner ring disposed on an upper peripheral portion of the substrate support;
an outer ring disposed on the peripheral part to surround the inner ring;
a plasma generator configured to generate plasma inside the chamber; and
a controller, wherein
the inner ring includes a first projection having an annular shape and protruding outward relative to the substrate support,
the outer ring includes a second projection having an annular shape, protruding inward relative to the peripheral part, and overlapping the first projection of the inner ring in a top view, and
the peripheral part is movable with respect to the substrate support in a direction approximately perpendicular to a substrate support surface of the substrate support.

9. The plasma processing apparatus according to claim 8, wherein the first projection of the inner ring is located below the second projection of the outer ring in an up-down direction.

10. The plasma processing apparatus according to claim 8, wherein a gap is provided between the substrate support and the peripheral part.

11. The plasma processing apparatus according to claim 10, wherein the first projection of the inner ring and the second projection of the outer ring overlap above the gap in the top view.

12. The plasma processing apparatus according to claim 8, wherein
the first projection of the inner ring includes a first flat plate portion extending outward and a first protruding portion extending upward, and
the second projection of the outer ring includes a second flat plate portion extending inward and a second protruding portion extending downward.

13. The plasma processing apparatus according to claim 8, wherein the peripheral part includes a pin configured to move the outer ring in an up-down direction.

14. An edge ring for a plasma processing apparatus, the edge ring comprising:
an inner ring including, on an outer peripheral surface, a first projection extending outward; and
an outer ring including, on an inner peripheral surface, a second projection extending inward, wherein
the first projection of the inner ring and the second projection of the outer ring overlap in a top view,
an upper surface of the outer ring is higher than an upper surface of the inner ring, and
a first distance between an outer periphery of the first projection of the inner ring and the inner peripheral surface of the outer ring facing the outer periphery of the first projection in a radial direction is shorter than a second distance between an inner periphery of the second projection of the outer ring and the outer peripheral surface of the inner ring facing the inner periphery of the second projection in the radial direction.

15. The edge ring according to claim 14, wherein the outer ring includes a lower projection extending downward from an inner peripheral side thereof and configured to protect a ceramic layer of a ring support supporting the outer ring.
